(19) United States
(12) Patent Application Publication
(10) Pub. No.: US 2025/0370037 A1
(43) Pub. Date: Dec. 4, 2025

(54) CHIP QUALITY TESTING OPTIMIZATION

(71) Applicant: NVIDIA Corporation, Santa Clara, CA (US)

(72) Inventors: Divyansh Jain, Newark, CA (US); Vivek Dubey, San Jose, CA (US); Peter Hung, Cupertino, CA (US); Keith Katcher, Del Mar, CA (US); Sreeramana Kommareddy, Santa Clara, CA (US)

(21) Appl. No.: 18/733,685

(22) Filed: Jun. 4, 2024

(51) Int. Cl. G01R 31/28; G06N 20/00

(52) U.S. Cl. CPC G01R 31/2894; G01R 31/2846; G06N 20/00

(57) ABSTRACT

Testing a semiconductor can be time-consuming as the chip architecture becomes more complex. Testing the possible scenarios becomes increasingly difficult. Chip quality characteristics relating to the chips on a wafer can be used to estimate a probability or rating relating to bypassing system-level testing (SLT). A chip can bypass SLT if there is a high likelihood of passing SLT. Thousands of chip characteristics can be received from wafer testing, chip probe testing, environmental parameters, factory parameters, and other parameters. A chip quality model can use chip quality characteristics as input to generate chip group and SLT parameters. The chip quality model can be a machine learning model or other types of machine learning systems. The chip group parameter or the SLT parameter can be used to direct the testing path of a chip where some chips can bypass SLT thereby saving production time.

### TECHNICAL FIELD

This application is directed, in general, to semiconductor testing and, more specifically, to optimizing system-level testing.

### BACKGROUND

Testing semiconductors, such as integrated circuits or systems on a chip, can be time-consuming and complex, especially as semiconductors become more complex and tightly packed with components. Chips at various locations on a wafer are known to have varying quality level differences. Repairs to a chip may be performed at various stages of manufacturing and testing of the chip. Repaired chips may result in quality concerns for those chips. It would be beneficial to shorten the testing cycle for chips with a likelihood of higher quality.

### SUMMARY

In one aspect, a method is disclosed. In one embodiment, the method includes (1) receiving a set of chip quality characteristics for a chip during a testing phase of the chip, wherein the chip is a semiconductor and the testing phase occurs before a time when the chip is transported to a customer, (2) aligning each chip quality characteristic in the set of chip quality characteristics with characteristic data of a chip quality model, wherein the chip quality model is a machine learning model, (3) generating an output of the chip quality model using the set of chip quality characteristics and respective characteristic data that is aligned, and (4) communicating the output, wherein the output indicates a chip group parameter for the chip and indicates a system-level test (SLT) parameter for the chip, where the chip group parameter recommends a chip group.

In a second aspect, a system is disclosed. In one embodiment, the system includes (1) a receiver, operational to receive a set of chip quality characteristics for a chip during a testing phase of the chip, wherein the chip is a semiconductor, and (2) a chip quality evaluator, implemented on one or more processors, and operational to align each chip quality characteristic in the set of chip quality characteristics with characteristic data of a chip quality model, generating an output from the chip quality model using the set of chip quality characteristics and respective characteristic data that is aligned, and communicate the output, wherein the output indicates a chip group parameter for the chip and the output indicates a SLT parameter for the chip, where the chip group parameter recommends a chip group.

In a third aspect, a computer program product having a series of operating instructions stored on a non-transitory computer-readable medium that directs a data processing apparatus when executed thereby to perform operations to generate an output for a chip is disclosed. In one embodiment the computer program product includes (1) receiving a set of chip quality characteristics for the chip during a testing phase of the chip, wherein the chip is a semiconductor and the testing phase occurs before a time when the chip is transported to a customer, (2) aligning each chip quality characteristic in the set of chip quality characteristics with characteristic data of a chip quality model, wherein the chip quality model is a machine learning model, (3) generating the output of the chip quality model using the set of chip quality characteristics and respective aligned characteristic data, and (4) communicating the output, wherein the output indicates a chip group parameter for the chip and indicates a SLT parameter for the chip, where the chip group parameter recommends a chip group.

### BRIEF DESCRIPTION

Reference is now made to the following descriptions taken in conjunction with the accompanying drawings, in which:

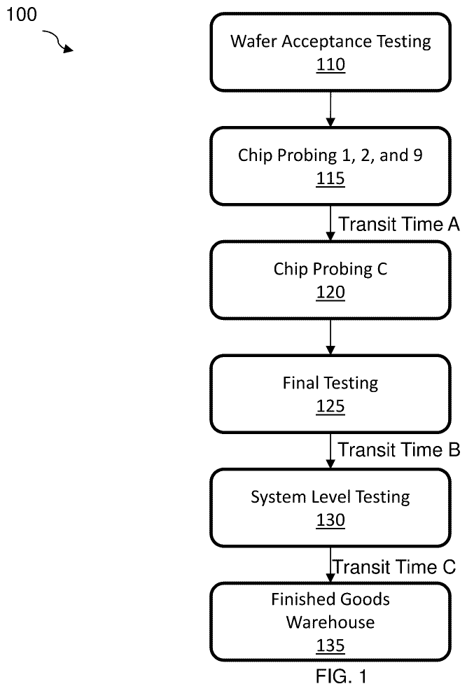

FIG. 1 is an illustration of a diagram of an example chip testing flow;

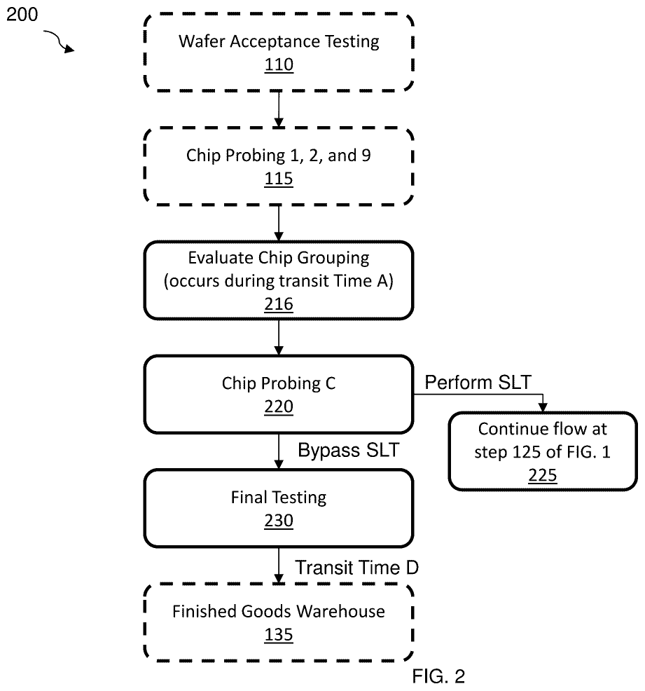

FIG. 2 is an illustration of a diagram of an example revised chip testing flow;

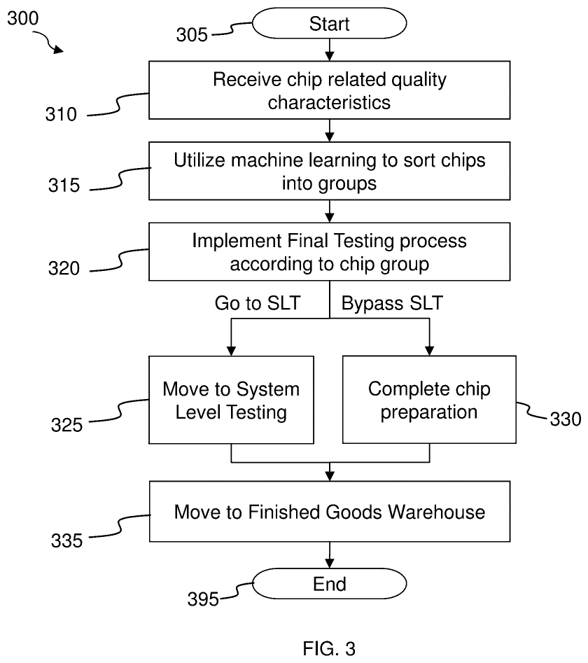

FIG. 3 is an illustration of a flow diagram of an example method for using a chip quality model to adjust a chip testing process;

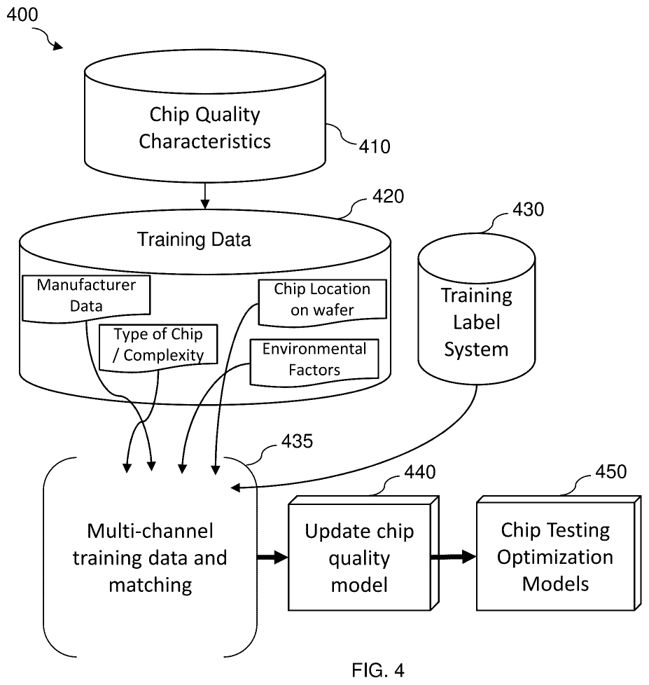

FIG. 4 is an illustration of a diagram of an example chip quality model training flow;

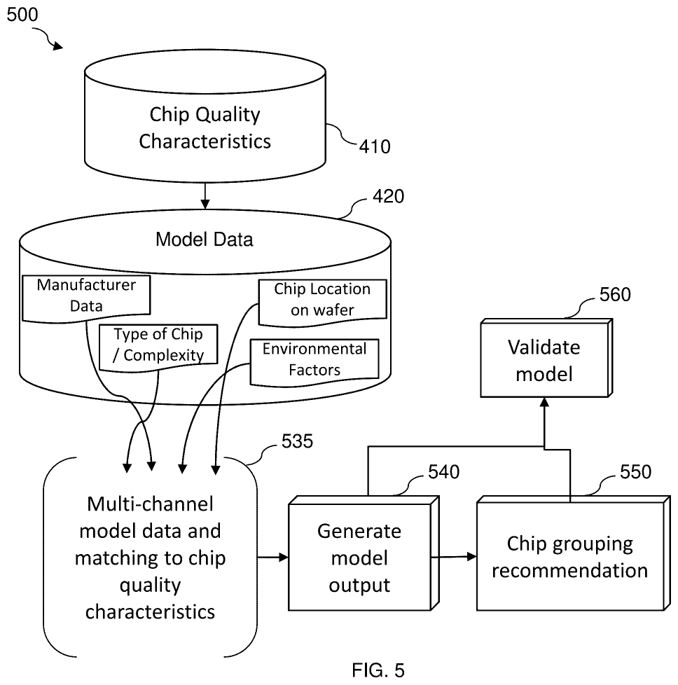

FIG. 5 is an illustration of a diagram of an example validation process;

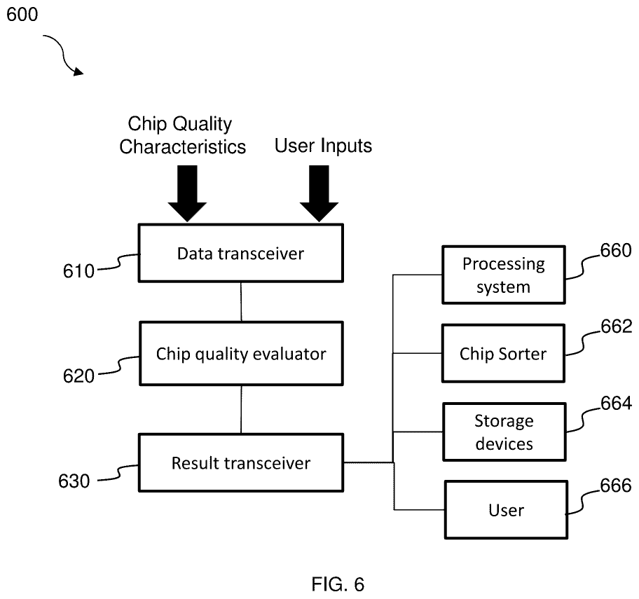

FIG. 6 is an illustration of a block diagram of an example chip quality system; and

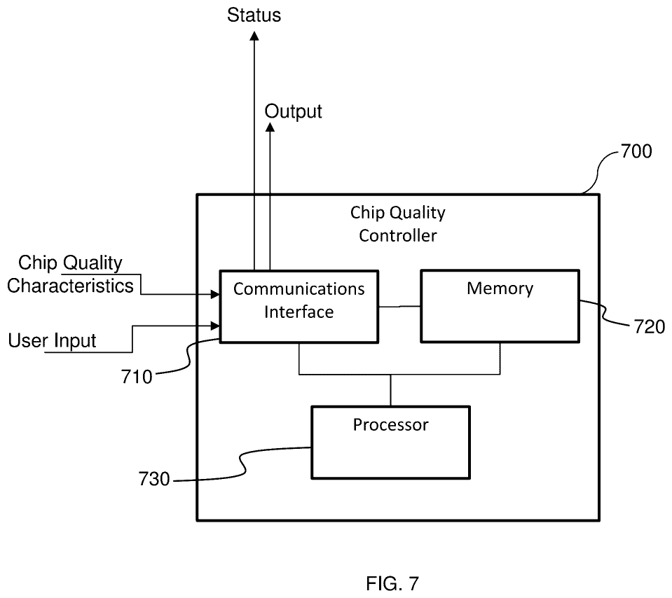

FIG. 7 is an illustration of a block diagram of an example of a chip quality controller according to the principles of the disclosure.

### DETAILED DESCRIPTION

The process of manufacturing a semiconductor, such as an integrated circuit (IC) or system on a chip (SoC) encompasses many steps. After the wafer is manufactured, where the wafer contains two or more chips, various testing stages are conducted. In some of these stages, a chip can be repaired, can have some functionality disabled, or can be marked as unusable. In some aspects, the testing can result in describing a probability or rating representing the quality of each respective chip on the wafer.

Testing a chip takes time. Reducing the number of testing steps or testing stages can improve the throughput speed, allowing a quality chip to reach a warehouse stage faster. A warehouse stage can be where the chip is prepared and ready for shipment to a customer. Moving from one test environment to another test environment can take time. If a testing stage can be bypassed, then the movement time to that test environment can be saved, as well as the time it takes to perform the tests at that stage. This in turn can improve the delivery time to the warehouse.

System-level testing (SLT) in semiconductor chip production refers to the testing process that verifies the functionality and performance of a complete IC or SoC after it has been manufactured. SLT can be conducted to ensure that the chip meets the specified requirements and functions correctly in its intended application. SLT plays a role in ensuring the quality and functionality of the semiconductor chips before they are deployed in real-world applications or delivered to customers. SLT can help identify and rectify issues or defects that may affect the chip's performance or reliability, which can ultimately improve the overall product quality.

In some aspects, SLT can be performed after the individual components of the chips, such as the logic circuits, memory, and peripherals, have been fabricated and assembled. SLT involves subjecting the chip to a series of test cases or stimuli that simulate real-world operating conditions. The purpose can be to identify defects, errors, or performance issues that may have occurred during the manufacturing process.

While SLT in semiconductor chip production can be important for ensuring the quality and functionality of chips, SLT does have disadvantages. (1) Cost: SLT can be costly, especially for complex chips or SoCs. SLT utilizes sophisticated test equipment and setups to replicate real-world operating conditions. The testing process itself can be time-consuming, leading to increased production costs. (2) Test Development: Developing test cases and stimuli for SLT can be challenging and time-consuming. As chips become more complex, creating comprehensive test cases that cover various possible scenarios becomes increasingly difficult. This complexity can impact the efficiency and effectiveness of SLT. (3) Accessibility and Probing Challenges: Accessing internal nodes or signals within the chip for testing can be difficult. As chips become smaller and more integrated, physical access to specific nodes can be limited. This limitation can hinder the ability to probe and measure signals accurately during SLT.

(4) Debugging Complexity: Identifying the root cause of a failure or issue during SLT can be complex. With multiple components and interactions involved, pinpointing the exact location or source of a problem can be challenging. This can lead to longer debugging times and delays in the production process. (5) Test Coverage Limitations: Achieving complete test coverage at the system level is challenging. The vast number of possible scenarios and interactions within a chip makes it difficult to test the combinations exhaustively. As a result, there is a possibility of undetected defects or issues that may surface later during actual system operation.

(6) Test Time and Throughout: SLT can require longer test times compared to lower-level tests. This can affect the overall production throughput and slow down the manufacturing process. Balancing the need for thorough testing with the desire for efficient production is a challenge that this disclosure attempts to address. (7) Early Test Equipment Failure: Sockets can be expensive and extensive testing can lead to costly repairs and equipment breakdown.

This disclosure presents processes that can improve the accuracy of identifying chips with a high probability of passing SLT. These chips can then be recommended to bypass SLT saving the movement time of chips to that testing area and saving the time of performing the SLT. This recommendation can be represented as a probability of passing SLT or a rating of SLT performance (i.e., an SLT parameter).

After manufacturing the wafer, multistep chip probing tests can be performed. The initial test run by the manufacturer on the wafer and the subsequent chip probing tests can generate various data points for the chip, forming a set of chip quality characteristics. The set of chip quality characteristics can be used as input into a chip quality model, where the chip quality model can be a machine learning model, a deep learning neural network model, or other types of machine learning systems. In some aspects, the chip quality model can generate an output including the SLT parameter (e.g., a recommendation on whether to bypass SLT or not to bypass SLT). In some aspects, the output can include a chip group parameter representing a grouping of the chip with other chips. The groups can be identified in various ways, for example, they can be sorted in order of probability of passing SLT.

A factory controller or system, or a testing controller or system, can direct the chip being analyzed to a testing path using the output of the chip quality model. For example, one testing path can include SLT, while a different testing path bypasses SLT. Bypassing SLT can result in time savings, for example, 24-48 hours of saved time which includes moving the chip to the SLT testing area and performing the SLT.

Turning now to the figures, FIG. 1 is an illustration of a diagram of an example chip testing flow 100. Chip testing flow 100 demonstrates a conventional testing flow for chips starting at a point after the wafer has been manufactured and before the individual chips are shipped to customers.

Chip testing flow 100 starts at a wafer acceptance testing 110. In some aspects, this can be performed by the chip manufacturer. Chip probing 1, 2, and 9 are performed next. In some aspects, chip probing 1 (CP1) is room-temperature testing, chip probing (CP2) is high-temperature testing, and chip probing 9 (CP9) is an algorithm applied to CP1 and CP2. Moving to a chip probing combined (CPC) 120 occurs during a transit time A. Transit time A can be of varying lengths, and in some aspects can be about 30 minutes. CPC 120 testing is conducted. In some aspects, it is during CPC 120 when the individual chips are broken or separated from the wafer and mounted on a substrate.

Final testing 125 occurs next, for example, running current through the chip to verify the voltages at checkpoints in the chip. After this step, chips can be transited to a SLT 130 area. This transit time is the transit time B. After SLT 130, the chip can be moved to finished goods warehouse 135 during transit time C. Finished goods warehouse 135 can be where the chip can be prepared and shipped to a customer. The time from final testing 125 to the end of SLT 130 can be varying time intervals, for example, 24 to 48 hours. Actual SLT testing can take 60-90 minutes with the rest of the time spent on transit, packaging, and preparation work. This disclosure describes processes to eliminate the transit time B and SLT 130 step to reduce the time for a chip to be ready to ship to a customer in finished goods warehouse 135.

FIG. 2 is an illustration of a diagram of an example revised chip testing flow 200. Revised chip testing flow 200 is similar to chip testing flow 100 where the dotted boxes indicate steps that are the same as in chip testing flow 100. A new step, evaluate 216, is performed during transit time A so there is minimal or no impact on the testing flow path.

Evaluate 216 receives chip quality characteristics from one or more sources and applies those chip quality characteristics through a chip quality model. The chip quality model can be a deep learning neural network, a machine learning network, or other types of machine models. Chip quality characteristics can be received from the wafer manufacturer, from the CP1, CP2, or CP9 tests, factory sensors, test environment sensors, or from other sources. The chip quality characteristics can be one or more of parametric parameters, spatial parameters of the chip, historical parameters, repair history of the chip parameters, disabled components parameters, parameters of the neighbors of the chip, or environmental parameters.

In some aspects, the chip quality characteristics can be a chip location parameter to identify where on a wafer the chip is located. In some aspects, the chip quality characteristics can be a manufacturer parameter such as to specify common issues encountered when chips are manufactured by a specified vendor or using a specific type of manufacturing equipment. In some aspects, there can be 14,000 or more data elements available as chip quality characteristics. The chip quality model can be used to sort, weight, and process these data elements to generate the output.

Parametric parameters can be derived from tests performed earlier in the testing pipeline. Parametric parameters can encompass complete coverage of the chip, such as current leakage, minimum operating voltage, speed measurements, powershots, FTM2CLK, or VMAX parameters. Spatial parameters can represent where on the wafer the chip is located. For example, chips at the outermost edge are most likely to have defects and so will likely need SLT, while chips around the middle of the wafer (not the center) tend to have the highest reliability and can tend to need less testing.

Historical parameters can include chip probe testing historical parameters, manufacturing facility or testing facility historical parameters, or spatial historical parameters. For example, if new manufacturing technology is employed and over time it is observed that certain locations on the wafer experience improved chip quality, then that information can be used to update the chip quality model. Parameters from the wafer manufacturing machines can be used as part of the facility's historical parameters. For example, repair information on specific manufacturing machines can be incorporated in the parameters, or certain manufacturing peculiarities of specific wafer manufacturing machines can be captured in the chip quality model. In some aspects, manufacturing machine information can be limited as received from the manufacturer, so these chip quality characteristics may have a lower weight or be eliminated from the set of chip quality characteristics.

The repair history of the chip can be captured as chip quality characteristics. These parameters can reflect potential repairs made to the chip or the wafer in previous chip production or testing stages. For example, RAM or chip pin repairs may have been made in an earlier stage of the testing life cycle. In some aspects, certain parts or components of a chip can be disabled, where the chip can perform primary functions, while some functions are disabled. In some aspects, the disabled component parameters can be used in the chip quality model.

Parameters associated with a neighbor chip on the wafer of the chip being analyzed can be used as chip quality characteristics. For example, if a repair was made to a chip that is a neighbor of the chip being analyzed, then the potential quality of the analyzed chip may be reduced, depending on the type of repair. Environmental parameters can be used as chip quality characteristics. For example, environmental parameters can include temperature, humidity, or air pressure at the time of manufacturing or at the time that one of the testing procedures was conducted. In some aspects, other environmental parameters can be used, for example, a known accidental exposure to certain chemicals by the chip where the chemicals may adversely affect the chip.

Evaluate 216 can also receive user input parameters, for example, a weighting to apply to each chip quality characteristic. In some aspects, some chip quality characteristics may not be available from certain wafer manufacturers. In this scenario, a chip quality characteristic can be weighted such as to eliminate it from consideration in the chip quality model, whereas when the data is available, a different weighting can be used. In some aspects, users can alter the weightings used by the chip quality model, for example, to override parameters used by the chip quality model. In some aspects, users can override the output of the chip quality model such as when a problem occurs on the factory floor and changes to the chip testing flow are needed. In some aspects, users can fine-tune the number of chips that bypass SLT, such as to alter a limit applied to a chip quality characteristic. For example, a voltage drop of 10% for a certain test can normally be labeled as ok to bypass SLT, and adjusted to 9% if a user determines that fewer chips are to bypass SLT. A user can use chip demand and factory environment parameters when making these determinations.

A CPC testing 220 step is performed after transit time A. CPC testing 220 varies from CPC testing 120 in that CPC testing 220 incorporates a decision process on where to move the chip. Using the output of the chip quality model, the chip can be identified as belonging to one of two or more groups. Each group can follow two or more different flow paths for the chip. For example, one group can be identified as bypassing SLT, a second group can be identified as needing SLT, and a third group can be identified as bypassing SLT when certain other criteria are met. An example of other criteria can be the intended customer of the chip and its intended usage so that chip usages that are more tolerant can accept a chip that bypasses some of the testing steps.

In aspects where the output of the chip quality model indicates that SLT is to be performed, then the flow proceeds to step 225 which proceeds to final testing 125 and continues the flow as shown in FIG. 1. In aspects where the output of the chip quality model indicates that SLT is to be bypassed, then the flow continues to final testing 230. Final testing 230 is similar to final testing 125 with an added process to perform etching, fusing, or identification procedures. For example, chip characteristics can be fused onto the chip. Chip testing flow 200 continues through transit time D to finished goods warehouse 135, where transit time D is less than the combined transit time B and transit time C.

FIG. 3 is an illustration of a flow diagram of an example method 300 for using a chip quality model to adjust a chip testing process. Method 300 can be performed on a computing system, for example, chip quality system 600 of FIG. 6 or chip quality controller 700 of FIG. 7. The computing system can be one or more processors in various combinations (e.g., CPUs, GPUS, SIMDs, or other types of processors), a data center, a cloud environment, a server, a laptop, a mobile device, a smartphone, a PDA, or other computing system capable of receiving the thread requests, and capable of executing threads in parallel. Method 300 can be encapsulated in software code or in hardware, for example, an application, code library, code module, dynamic link library, module, function, RAM, ROM module, and other software and hardware implementations. The software can be stored in a file, database, or other computing system storage mechanism. Method 300 can be partially implemented in software and partially in hardware. Method 300 can perform the steps for the described processes, for example, directing the testing path for a chip.

Method 300 starts at a step 305 and proceeds to a step 310. In step 310, chip quality characteristics can be received during a chip testing phase. Chip quality characteristics can be received from one or more sensors or systems. For example, chip quality characteristics can be received from a data store, a server, a manufacturing machine, a testing machine, a factory management system, a wafer controller, or other types of systems or controllers. In some aspects, sensors can be used to collect the chip quality characteristics. For example, sensors can include visual data captured by a camera, acoustic data, x-ray data, infrared data, ultraviolet data, or other sensor types can be used. In some aspects, sensors can measure temperature, humidity, air pressure, or other environmental parameters. In some aspects, sensor data can be communicated to the chip quality system as disclosed herein. In some aspects, sensor data can be communicated to another system, such as a data store, and then the other system can communicate to the chip quality system as disclosed herein.

Chip quality characteristics can include characteristics (e.g., parameters) in the areas of parametric parameters from earlier tests, spatial parameters, historical parameters, repair parameters, disabled component parameters, neighbor chip parameters, environmental parameters, or other types of parameters. In some aspects, input parameters can be received. Input parameters can include weighting of the chip quality characteristics, indicators of chip quality characteristics that are to be ignored in the analysis, algorithms to utilize (for example, if there is more than one chip quality model, one of the models can be selected to be used), a targeted number of chips to bypass SLT, user overrides (for example, if other criteria necessitate a change to the output of a chip quality model such as an issue on the factory floor or chip demand by customers), a threshold for a chip quality characteristics, a minimum threshold probability or rating to allow for bypassing SLT, or other types of input parameters.

In a step 315, chips can be sorted into two or more groups. The sorting algorithm, performed by the chip quality model, utilizes the received chip quality characteristics and the input parameters. The chip group parameter and the SLT parameter for the chip are the outputs of the chip quality model. For example, one group can be identified as having the highest probability of bypassing SLT, and a second group can be identified as having the lowest probability of bypassing SLT. In some aspects, one or more additional groups can be defined with varying probabilities to bypass SLT. These groupings can be used, such as to target a specific number of chips to bypass SLT where the groups can be ordered in probability or rating until either the number of chips to bypass SLT is reached, or the probability or rating to bypass SLT has reached a minimum threshold as specified in the input parameters. In some aspects, the grouping algorithm can take into account other factors not related to SLT. For example, manufacturing machine identifiers can be used to group chips which can allow processes to look back and estimate quality as produced by respective manufacturing machines which can be useful when there is limited information from the manufacturer about the machines.

In a step 320, a final testing process can be implemented. The final testing can follow industry standards for such testing. At the end of step 320, a decision can be made using the chip group parameter or SLT parameter as determined in step 315. Chips that have been identified as moving to SLT move to a step 325. Chips that have been identified as bypassing SLT move to a step 330.

In step 330, the chip enters a finalization stage. For example, identifiers are fused onto the chip or other information can be etched into the surface silicon of the chip. Method 300 proceeds to a step 335.

In step 325, the chip moves to the SLT stage. The SLT stage is performed. Method 300 proceeds to step 335. In step 335, the chip can be packaged and moved to the finished goods warehouse, and be ready to ship to a customer. Method 300 ends at a step 395.

FIG. 4 is an illustration of a diagram of an example chip quality model training flow 400, such as implemented by a training system. Chip quality model training flow 400 can be used to train a machine learning system using one or more machine learning models of chip quality algorithms. A data store 410 can receive the chip quality characteristics collected from one or more sensors (such as visual data captured by a camera, acoustic data, x-ray data, infrared data, ultraviolet data, temperature data, humidity data, air pressure data, or other sensor types), testing systems, factory systems, manufacturing systems, manufacturing machines, or other processes or systems that can identify chip quality characteristics. In a process 420, the received chip quality characteristics can be sorted and grouped according to the type of characteristic, where the characteristic was received from, the reliability of the characteristic data, or using other grouping factors. In some aspects, the set of chip quality characteristics can be preprocessed to remove outlier data elements and to normalize parameters representing chip quality characteristics within the set of chip quality characteristics.

In a process 435, the chip quality characteristics data can be labeled for training of the chip quality models. The training labels can be obtained from a training label system 430, such as legacy interpretation, user operation, label fusion, or using a cross-validation workflow. The trained chip quality models can be used to process the chip quality characteristics in a process 440 to generate an updated chip quality model. Each chip quality model can generate a different output. For example, one chip quality model can be generated using the assumption that manufacturing machine specifications are available and another chip quality model can be generated using the assumption that manufacturing machine specifications are not available. In a process 450, the updated chip quality models can be verified and stored for further use.

FIG. 5 is an illustration of a diagram of an example validation process 500. Validation process 500 builds on FIG. 4 by using the trained chip quality models. The received chip quality characteristics can be processed through chip quality models 535 to generate various result parameters. In process 540, the result parameters can be combined to produce an output, such as a group parameter (e.g., a group identifier) and an SLT parameter (e.g., an SLT recommendation). In a process 550, the output can be used to generate a recommendation for the subsequent testing path of a chip. In some aspects, this recommendation can be overridden by a user or an input parameter. The recommendation can be communicated to a user, a factory controller, a testing system, or other types of controllers or systems as an input parameter.

In some aspects, an optional process 560 can be performed to validate the output of the chip quality model using the training data and then update the chip quality model if needed. Process 560 can be performed by a validator system or other system. For example, validating the chip group parameter and the SLT parameter can be achieved using the training data. The results of the validating can be used to update the chip quality model.

FIG. 6 is an illustration of a block diagram of an example chip quality system 600. Chip quality system 600 can be implemented in one or more computing systems or one or more processors. In some aspects, chip quality system 600 can be implemented using a chip quality controller such as chip quality controller 700 of FIG. 7. Chip quality system 600 can implement one or more aspects of this disclosure, such as method 300 of FIG. 3.

Chip quality system 600, or a portion thereof, can be implemented as an application, a code library, a dynamic link library, a function, a module, a header file, other software implementation, or combinations thereof. In some aspects, chip quality system 600 can be implemented in hardware, such as a ROM, a graphics processing unit, or other hardware implementation. In some aspects, chip quality system 600 can be implemented partially as a software application and partially as a hardware implementation. Chip quality system 600 is a functional view of the disclosed processes and an implementation can combine or separate the described functions in one or more software or hardware systems.

Chip quality system 600 includes a data transceiver 610, a chip quality evaluator 620, and a result transceiver 630. The output, e.g., the group parameter or SLT parameter for a chip from chip quality evaluator 620, can be communicated to a data receiver, such as one or more of a processing system 660 (one or more combinations of processors or processing cores, such as a chip testing processing system), one or more chip sorters 662 (such as a chip sorting system), one or more storage devices 664, or one or more users 666. The output can be used to provide a recommendation to a system on whether a chip can bypass SLT while maintaining a specified threshold of probability or rating on the quality of the chip.

Data transceiver 610 can receive the chip quality characteristics, as well as operational parameters (e.g., input parameters), such as the probability or rating threshold for bypassing SLT, weighting parameters for respective chip quality characteristics, a specified model of chip quality model, or other input or operational parameters. In some aspects, data transceiver 610 can be part of chip quality evaluator 620.

Result transceiver 630 can communicate one or more outputs, to one or more data receivers, such as processing systems 660, chip sorters 662, storage devices 664, users 666, or other related systems, whether located proximate result transceiver 630 or distant from result transceiver 630. Data transceiver 610, chip quality evaluator 620, and result transceiver 630 can be, or can include, conventional interfaces configured for transmitting and receiving data. Data transceiver 610, chip quality evaluator 620, or result transceiver 630 can be implemented as software components, for example, a virtual processor environment, as hardware, for example, circuits of an integrated circuit, or combinations of software and hardware components and functionality. The functionality described for these components remains intact regardless of how the functionality is implemented.

Chip quality evaluator 620 (e.g., one or more processors such as processor 730 of FIG. 7) can implement the analysis and algorithms as described herein utilizing the input parameters and chip quality characteristics. Chip quality evaluator 620 can be one or more of a multicore processor, a multiprocessor system, or a streaming multiprocessor. Chip quality evaluator 620 can be implemented by a central processing unit (CPU), a graphics processing unit (GPU), or other types of processors.

A memory or data storage system of chip quality evaluator 620 (such as a core cache, L1 cache, L2 cache, or other memory systems) can be configured to store the processes and algorithms for directing the operation of chip quality evaluator 620. Chip quality evaluator 620 can include a processor that is configured to operate according to the analysis operations and algorithms disclosed herein, and an interface to communicate (transmit and receive) data.

FIG. 7 is an illustration of a block diagram of an example of a chip quality controller 700 according to the principles of the disclosure. Chip quality controller 700 can be stored on one computer or multiple computers. The various components of chip quality controller 700 can communicate via wireless or wired conventional connections. A portion or a whole of chip quality controller 700 can be located at one or more locations. In some aspects, chip quality controller 700 can be part of another system (e.g., processor, core, server, or other systems), and can be integrated with one device, such as a part of a processing system. Chip quality controller 700 represents a demonstration of the functionality employed for the disclosure, and implementations can use a variety of devices, for example, circuits of a processor, dedicated processors, virtual systems, servers, other computing or processing systems, be in software or hardware, or various combinations thereof.

Chip quality controller 700 can be configured to perform the various functions disclosed herein including receiving input parameters and generating results from execution of the methods and processes described herein, such as determining a group parameter for a chip or a SLT parameter for a chip. Chip quality controller 700 includes a communications interface 710, a memory 720, and a processor 730.

Communications interface 710 is configured to transmit and receive data. For example, communications interface 710 can receive the input parameters and chip quality characteristics. Communications interface 710 can transmit the output or interim outputs. In some aspects, communications interface 710 can transmit a status, such as a success or failure indicator of chip quality controller 700 regarding receiving the various inputs, transmitting the generated outputs, or producing the results.

In some aspects, processor 730 can perform the operations as described by chip quality evaluator 620. Communications interface 710 can communicate via communication systems used in the industry. For example, wireless or wired protocols can be used. Communication interface 710 is capable of performing the operations as described for data transceiver 610 and result transceiver 630 of FIG. 6.

Memory 720 can be configured to store a series of operating instructions that direct the operation of processor 730 when initiated, including supporting code representing the chip quality models. Memory 720 is a non-transitory computer-readable medium. Multiple types of memory can be used for the data storage systems and memory 720 can be distributed.

Processor 730 can be one or more processors. Processor 730 can be a combination of processor types, such as a CPU, a GPU, a single instruction multiple data (SIMD) processor, or other processor types. Processor 730 can be configured to produce the output, one or more interim outputs, and statuses utilizing the received inputs. Processor 730 can determine the output using parallel processing. Processor 730 can be an integrated circuit. In some aspects, processor 730, communications interface 710, memory 720, or various combinations thereof, can be an integrated circuit. Processor 730 can be configured to direct the operation of chip quality controller 700. Processor 730 includes the logic to communicate with communications interface 710 and memory 720, and perform the functions described herein. Processor 730 is capable of performing or directing the operations as described by chip quality evaluator 620 of FIG. 6.

A portion of the above-described apparatus, systems or methods may be embodied in or performed by various digital data processors or computers, wherein the computers are programmed or store executable programs of sequences of software instructions to perform one or more of the steps of the methods. The software instructions of such programs may represent algorithms and be encoded in machine-executable form on non-transitory digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, or functions, systems or apparatuses described herein. The data storage media can be part of or associated with digital data processors or computers.

The digital data processors or computers can be comprised of one or more GPUs, one or more CPUs, one or more of other processor types, or a combination thereof. The digital data processors and computers can be located proximate to each other, proximate to a user, in a cloud environment, a data center, or located in a combination thereof. For example, some components can be located proximate to the user, and some components can be located in a cloud environment or data center.

The GPUs can be embodied on one semiconductor substrate, included in a system with one or more other devices such as additional GPUs, a memory, and a CPU. The GPUs may be included on a graphics card that includes one or more memory devices and is configured to interface with a motherboard of a computer. The GPUs may be integrated GPUs (iGPUs) that are co-located with a CPU on one chip. Configured or configured to means, for example, designed, constructed, or programmed, with the necessary logic and/or features for performing a task or tasks.

Portions of disclosed examples or embodiments may relate to computer storage products with a non-transitory computer-readable medium that have program code thereon for performing various computer-implemented operations that embody a part of an apparatus, device or carry out the steps of a method set forth herein. Non-transitory used herein refers to all computer-readable media except for transitory, propagating signals. Examples of non-transitory computer-readable media include, but are not limited to: magnetic media such as hard disks, floppy disks, and magnetic tape; optical media such as CD-ROM disks; magneto-optical media such as floppy disks; and hardware devices that are specially configured to store and execute program code, such as ROM and RAM devices. Configured or configured to means, for example, designed, constructed, or programmed, with the necessary logic and/or features for performing a task or tasks. Examples of program code include both machine code, such as produced by a compiler, and files containing higher level code that may be executed by the computer using an interpreter.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, delctions, substitutions, and modifications may be made to the described embodiments. It is also to be understood that the terminology used herein is for the purpose of describing particular embodiments only, and is not intended to be limiting, since the scope of the present disclosure will be limited only by the claims. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

Each of the aspects disclosed in the SUMMARY can have one or more of the following additional elements in combination. Element 1: wherein the set of chip quality characteristics include one or more of a type of chip, a manufacturer parameter, an environment parameter, or a chip location parameter. Element 2: wherein the chip is an integrated circuit (IC) or a system on a chip (SoC). Element 3: wherein the output is communicated to a validator system. Element 4: validating the chip group parameter and the SLT parameter using training data. Element 5: updating the chip quality model with results of the validating. Element 6: wherein the output is communicated to a system or a process that directs the chip, after a chip probing combined (CPC) test, to a final test (FT) without system-level testing when the SLT parameter indicates that system-level testing is to be bypassed. Element 7: wherein the method executes prior to a CPC test and the method executes during a transit time of the chip. Element 8: wherein the output further includes training chip quality characteristics and is utilized to update the chip quality model. Element 9: wherein the aligning each chip quality characteristic further utilizes a set of training labels representing respective chip quality characteristics to improve results of the chip quality model. Element 10: wherein the set of chip quality characteristics is preprocessed to remove outlier data elements Element 11: wherein the set of chip quality characteristics is preprocessed to normalize parameters representing chip quality characteristics within the set of chip quality characteristics. Element 12: wherein user inputs are utilized to modify the set of chip quality characteristics. Element 13: further comprising a machine learning system, operational to communicate with the chip quality evaluator. Element 14: further comprising a machine learning system, operational to execute the chip quality model using the set of chip quality characteristics to generate the output. Element 15: further comprising a training system, operational to utilize the output to update the chip quality model to improve an accuracy of the output. Element 16: further comprising a validator system, operational to utilize the output to validate the output against the chip quality model. Element 17: wherein the receiver is further operational to receive user input parameters, wherein the user input parameters include a weighting for each of the chip quality characteristics. Element 18: further comprising a transceiver, operational to communicate the output to a chip sorter system or a chip testing processing system. Element 19: wherein the machine learning model is a deep learning neural network. Element 20: wherein the operations are performed on a chip testing system or a cloud environment. Element 21: further comprising validating the output using training data Element 22: further comprising updating the chip quality model using results from the validating.

What is claimed is:

1. A method, comprising:
receiving a set of chip quality characteristics for a chip during a testing phase of the chip, wherein the chip is a semiconductor and the testing phase occurs before a time when the chip is transported to a customer;
aligning each chip quality characteristic in the set of chip quality characteristics with characteristic data of a chip quality model, wherein the chip quality model is a machine learning model;
generating an output of the chip quality model using the set of chip quality characteristics and respective characteristic data that is aligned; and
communicating the output, wherein the output indicates a chip group parameter for the chip and indicates a system-level test (SLT) parameter for the chip, where the chip group parameter recommends a chip group.

2. The method as recited in claim 1, wherein the set of chip quality characteristics include one or more of a type of chip, a manufacturer parameter, an environment parameter, or a chip location parameter.

3. The method as recited in claim 1, wherein the chip is an integrated circuit (IC) or a system on a chip (SoC).

4. The method as recited in claim 1, wherein the output is communicated to a validator system, further comprising:
validating the chip group parameter and the SLT parameter using training data; and
updating the chip quality model with results of the validating.

5. The method as recited in claim 1, wherein the output is communicated to a system or a process that directs the chip, after a chip probing combined (CPC) test, to a final test (FT) without system-level testing when the SLT parameter indicates that system-level testing is to be bypassed.

6. The method as recited in claim 1, wherein the method executes prior to a CPC test and the method executes during a transit time of the chip.

7. The method as recited in claim 1, wherein the output further includes training chip quality characteristics and is utilized to update the chip quality model.

8. The method as recited in claim 1, wherein the aligning each chip quality characteristic further utilizes a set of training labels representing respective chip quality characteristics to improve results of the chip quality model.

9. The method as recited in claim 1, wherein the set of chip quality characteristics is preprocessed to remove outlier data elements and to normalize parameters representing chip quality characteristics within the set of chip quality characteristics.

10. The method as recited in claim 1, wherein user inputs are utilized to modify the set of chip quality characteristics.

11. A system, comprising:
a receiver, operational to receive a set of chip quality characteristics for a chip during a testing phase of the chip, wherein the chip is a semiconductor; and
a chip quality evaluator, implemented on one or more processors, and operational to align each chip quality characteristic in the set of chip quality characteristics with characteristic data of a chip quality model, generating an output from the chip quality model using the set of chip quality characteristics and respective characteristic data that is aligned, and communicate the output, wherein the output indicates a chip group parameter for the chip and the output indicates a system-level test (SLT) parameter for the chip, where the chip group parameter recommends a chip group.

12. The system as recited in claim 11, further comprising:
a machine learning system, operational to communicate with the chip quality evaluator and to execute the chip quality model using the set of chip quality characteristics to generate the output.

13. The system as recited in claim 11, further comprising:
a training system, operational to utilize the output to update the chip quality model to improve an accuracy of the output.

14. The system as recited in claim 11, further comprising:
a validator system, operational to utilize the output to validate the output against the chip quality model.

15. The system as recited in claim 11, wherein the receiver is further operational to receive user input parameters, wherein the user input parameters include a weighting for each of the chip quality characteristics.

16. The system as recited in claim 11, further comprising:
a transceiver, operational to communicate the output to a chip sorter system or a chip testing processing system.

17. A computer program product having a series of operating instructions stored on a non-transitory computer-readable medium that directs a data processing apparatus when executed thereby to perform operations to generate an output for a chip, the operations comprising:
receiving a set of chip quality characteristics for the chip during a testing phase of the chip, wherein the chip is a semiconductor and the testing phase occurs before a time when the chip is transported to a customer;
aligning each chip quality characteristic in the set of chip quality characteristics with characteristic data of a chip quality model, wherein the chip quality model is a machine learning model;
generating the output of the chip quality model using the set of chip quality characteristics and respective aligned characteristic data; and
communicating the output, wherein the output indicates a chip group parameter for the chip and indicates a system-level test (SLT) parameter for the chip, where the chip group parameter recommends a chip group.

18. The computer program product recited in claim 17, wherein the machine learning model is a deep learning neural network.

19. The computer program product recited in claim 17, wherein the operations are performed on a chip testing system or a cloud environment.

20. The computer program product recited in claim 17, further comprising:
validating the output using training data; and
updating the chip quality model using results from the validating.
